(19) United States
(12) Patent Application Publication
(10) Pub. No.: US 2018/0042121 A1
(43) Pub. Date: Feb. 8, 2018

(54) CIRCUIT BOARD WITH SOLDER THIEVES

(71) Applicant: Molex, LLC, Lisle, IL (US)

(72) Inventor: Ze-Li XIONG, Dongguan (CN)

(73) Assignee: Molex, LLC, Lisle, IL (US)

(21) Appl. No.: 15/657,386

(22) Filed: Jul. 24, 2017

(30) Foreign Application Priority Data
Aug. 5, 2016 (CN) 201610639104.6

(51) Int. Cl. H05K 3/34; H05K 1/11

(52) U.S. Cl. CPC H05K 3/3436; H05K 1/111; H05K 3/3468; H05K 2201/094

(57) ABSTRACT

A circuit board with solder thieves is provided that has a plurality of plug-in connector pads, a plurality of conductive traces, and first and second solder thieves. The plurality of plug-in connector pads are arranged in two rows on the circuit board. Each conductive trace connects with a plug-in connector pad. Both of the first solder thief and the second solder thief are provided on one side of the two rows of plug-in connector pads, the one side is away from an advancing direction of the circuit board during wave soldering. Each of an area of the first solder thief and an area of the second solder thief is greater than or equal to a sum of areas of two plug-in connector pads adjacent to corresponding one of the first solder thief and the second solder thief. Sizes of the solder thieves on the circuit board with solder thieves according to the present disclosure each are large enough to form a sufficient amount of traction force during wave soldering, so it will not leave solder projections, therefore it will not cause short circuit.

### RELATED APPLICATIONS

This application claims priority to Chinese Application No. 201610639104.6, filed Aug. 5, 2016, which is incorporated herein by reference in its entirety.

### TECHNICAL FIELD

The present disclosure relates to a circuit board, more particularly to a circuit board with solder thieves.

### BACKGROUND ART

As electronic products are developing toward miniaturization and digitization, circuit boards are also developing toward high density and high precision, so the process design of the circuit board is more and more complex, a pitch between pins of components is getting shorter and shorter.

Wave soldering is to make a molten solder to form a solder peak which meets the design requirement, and then make a circuit board on which components have been mounted in advance pass through the solder peak, so as to achieve a soft soldering process which makes a mechanical and electrical connection between a soldering terminal or pin of the component and a pad of the circuit board. A general process of the wave soldering is: inserting the component into a corresponding component hole of the pad, pre-coating soldering flux, preheating, wave soldering and checking.

When multi-row plug-in connectors are in wave soldering, metal pins of plug-in connectors will leave solder projections in an direction opposite to an advancing direction of a track, and the solder projections cannot be absorbed with respect to the last column of pins, and are easy to lap adjacent (upper, lower, left, right) pins, so as to cause short circuit.

In order to resolve the above problem, a method of preventing solder bridging during wave soldering of plug-in connectors on a printed circuit board (PCB) is disclosed in Chinese Patent Application Publication No. CN104105358A. As shown in FIG. 1, a printed circuit board 300 comprises a plurality of plug-in connector pads 320 arranged in rows which each are in a straight line, and a plurality of solder thieves 310 provided on one side of the plurality of plug-in connector pads 320, the one side is away from an advancing direction of the PCB during wave soldering. When each row of plug-in connectors is in wave soldering, one solder thief 310 is provided near the plug-in connector pad 320 which is the last one to be soldered. A width of the solder thief 310 (that is, a side length which is perpendicular to the advancing direction of the printed circuit board 300 during wave soldering) is greater than or equal to a diameter of the plug-in connector pad 320, preferably equal to the diameter of the plug-in connector pad 320.

However, although the above-mentioned prior art defines that the width of the solder thief 310 is greater than or equal to the diameter of the plug-in connector pad 320, when a solder projection has lapped the adjacent (upper, lower, left, right) pin, because an area of the solder thief 310 is less than a sum of areas of the two plug-in connector pads 320, the solder thief 310 of the above patent does not have sufficient traction force and is easy to still make the solder projection left so that a short circuit problem is caused.

In addition, since the solder thief 310 is only provided near the plug-in connector pad 320 which is the last one in each row, the circuit board 300 must be advanced in a single direction during wave soldering, otherwise it cannot prevent solder bridging and short circuit.

### SUMMARY

In order to solve the above problem, one object of the present disclosure is to provide a circuit board with solder thieves, which does not cause short circuit during wave soldering.

A further object of the present disclosure is to provide a circuit board with solder thieves and preventing short circuit, which will be not necessary to advance in a single advancing direction during wave soldering.

In order to achieve the above objects and other advantages, the present disclosure provides a circuit board with solder thieves, the circuit board comprises: a plurality of plug-in connector pads arranged in two rows on the circuit board; a plurality of conductive traces each connecting with one plug-in connector pad; and a first solder thief and a second solder thief, both of the first solder thief and the second solder thief are provided on one side of the two rows of plug-in connector pads, the one side is away from an advancing direction of the circuit board during wave soldering, each of an area of the first solder thief and an area of the second solder thief is greater than or equal to a sum of areas of two plug-in connector pads adjacent to corresponding one of the first solder thief and the second solder thief.

In an embodiment, each of the area of the first solder thief and the area of the second solder thief is greater than or equal to a sum of the areas of the two plug-in connector pads adjacent to the corresponding one of the first solder thief and the second solder thief and an area between the two plug-in connector pads.

In an embodiment, a sum of the area of the first solder thief and the area of the second solder thief is greater than or equal to a sum of areas of three plug-in connector pads adjacent to the first solder thief and second solder thief and an area among the three plug-in connector pads.

In an embodiment, the circuit board further comprises a third solder thief and a fourth solder thief, both of the third solder thief and the fourth solder thief are provided on the other side of the two rows of plug-in connector pads, the other side is opposite to the first solder thief and second solder thief, each of an area of the third solder thief and an area of the fourth solder thief is greater than or equal to a sum of areas of two plug-in connector pads adjacent to corresponding one of the third solder thief and the fourth solder thief.

In an embodiment, each of the area of the third solder thief and the area of the fourth solder thief is greater than or equal to a sum of the areas of the two plug-in connector pads adjacent to the corresponding one of the third solder thief and the fourth solder thief and an area between the two plug-in connector pads.

In an embodiment, a sum of the area of the third solder thief and the area of the fourth solder thief is greater than or equal to a sum of areas of three plug-in connector pads adjacent to the third solder thief and fourth solder thief and an area among the three plug-in connector pads.

In an embodiment, the first solder thief and the second solder thief are merged into a fifth solder thief, an area of the fifth solder thief is greater than or equal to a sum of areas of three plug-in connector pads adjacent to the fifth solder thief and an area among the three plug-in connector pads; the third solder thief and the fourth solder thief are merged into a sixth solder thief, an area of the sixth solder thief is greater than or equal to a sum of areas of three plug-in connector pads adjacent to the sixth solder thief and an area among the three plug-in connector pads.

The beneficial effect of the present disclosure lies in that: sizes of the solder thieves on the circuit board with solder thieves according to the present disclosure each are large enough to form a sufficient amount of traction force during wave soldering, so it will not leave solder projections, therefore it will not cause short circuit. Further, when the solder thieves are respectively provided on both sides of the plug-in connector pads, the circuit board does not have to be limited to a single advancing direction during wave soldering, which increases flexibility of the wave soldering process and avoids the loss caused by an improper advancing direction.

### BRIEF DESCRIPTION OF THE DRAWINGS

The present disclosure may be better understood from the following detailed description in combination with the Figures, a similar element is indicated by a like reference numeral in different embodiments, and in the Figures:

FIG. 1 is a schematic view of a circuit board with solder thieves in the prior art.

FIG. 2 is a schematic view of a circuit board with solder thieves of a first embodiment according to the present disclosure.

FIG. 3 is a schematic view of a circuit board with solder thieves of a second embodiment according to the present disclosure.

FIG. 4 is a schematic view of a circuit board with solder thieves of a third embodiment according to the present disclosure.

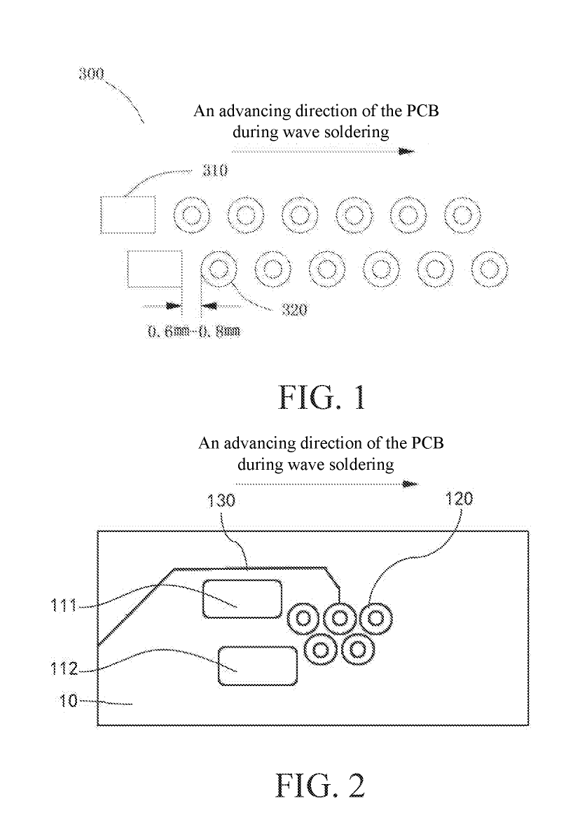

### DETAILED DESCRIPTION OF THE PREFERRED EMBODIMENTS

Hereinafter embodiments of the present disclosure will be described in detail with reference to the figures.

As shown in FIG. 2, a circuit board 10 of a first embodiment according to the present disclosure comprises a first solder thief 111, a second solder thief 112, a plurality of plug-in connector pads 120 and a plurality of conductive traces 130. The conductive traces 130 each connect with one of the plug-in connector pads 120, and the plurality of plug-in connector pads 120 are arranged in two rows on the circuit board 10, the first solder thief 111 and the second solder thief 112 are both provided on one side of the two rows of pads 120, the one side is away from an advancing direction of the circuit board 10 during wave soldering, and the two solder thieves 111, 112 are both rectangular. An area of the first solder thief 111 and an area of the second solder thief 112 each are greater than or equal to a sum of areas of two plug-in connector pads 120 adjacent to corresponding one of the first solder thief 111 and the second solder thief 112; preferably, the area of the first solder thief 111 and the area of the second solder thief 112 each are greater than or equal to a sum of the areas of the two plug-in connector pads 120 adjacent to the corresponding one of the first solder thief 111 and the second solder thief 112 and an area between the two plug-in connector pads 120. Further preferably, a sum of the area of the first solder thief 111 and the area of the second solder thief 112 is greater than or equal to a sum of the areas of three plug-in connector pads 120 adjacent to the first solder thief 111 and second solder thief 112 and an area among the three plug-in connector pads 120. Therefore, when the wave soldering is in a direction as shown in FIG. 2, one plug-in connector pad in a row can absorb a solder projection left by the previous one plug-in connector during wave soldering, the first solder thief 111 and the second solder thief 112 on the one side away from the advancing direction each are on the last soldering position of the corresponding row, and sizes of the two solder thieves 111,112 each are large enough to form a sufficient amount of traction force, so it will not leave the solder projections in positions of the two or even three plug-in connector pads 120 adjacent thereto, so as to effectively prevent short circuit.

FIG. 3 is a schematic view of a circuit board with solder thieves of a second embodiment according to the present disclosure. As shown in FIG. 3, the second embodiment according to the present disclosure is based on the first embodiment, a third solder thief 113 and a fourth solder thief 114 are further provided on the other side of the two rows of plug-in connector pads 120, the other side is opposite to the first solder thief 111 and second solder thief 112, that is, the circuit board 10 in the second embodiment comprises four rectangular solder thieves 111, 112, 113, 114. The other structures are the same as those described in the first embodiment. An area of each solder thief 111, 112, 113, 114 is greater than or equal to a sum of areas of two plug-in connector pads 120 adjacent to corresponding one of the solder thieves 111, 112, 113, 114; preferably, the area of each solder thief 111, 112, 113, 114 is greater than or equal to a sum of the areas of the two plug-in connector pads 120 adjacent to the corresponding one of the solder thieves 111, 112, 113, 114 and an area between the two plug-in connector pads 120. Further preferably, a sum of the area of the first solder thief 111 and the area of the second solder thief 112 is greater than or equal to a sum of areas of three plug-in connector pads 120 adjacent to the first solder thief 111 and second solder thief 112 and an area among the three plug-in connector pads 120; a sum of the area of the third solder thief 113 and the area of the fourth solder thief 114 is greater than or equal to a sum of the areas of three plug-in connector pads 120 adjacent to the third solder thief 113 and fourth solder thief 114 and an area among the three plug-in connector pads 120. Therefore, during wave soldering, sizes of the four above-mentioned solder thieves 111,112,113,114 each are large enough to form a sufficient amount of traction force, so it will not leave solder projections in positions of the two or even three plug-in connector pads 120 adjacent thereto, so as to effectively prevent short circuit. At the same time, because there are the solder thieves 111,112,113,114 respectively provided on both sides of the plug-in connector pads 120, the circuit board 10 does not have to be limited to a single advancing direction during wave soldering, which increases flexibility of the wave soldering process and avoids the loss caused by an improper advancing direction.

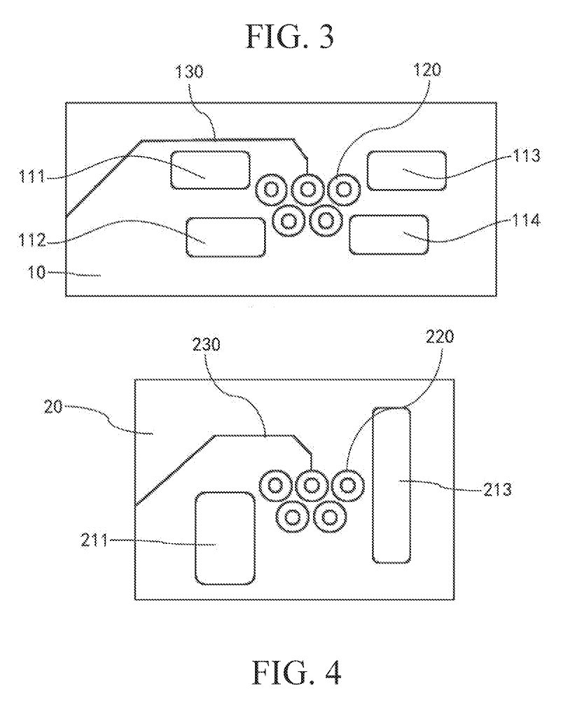

FIG. 4 is a schematic view of a circuit board with solder thieves of a third embodiment according to the present disclosure. As shown in FIG. 4, differences of the third embodiment according to the present disclosure from the second embodiment are in that: the third embodiment merges the first solder thief 111 and the second solder thief 112 in the second embodiment into a fifth solder thief 211, and merges the third solder thief 113 and the fourth solder thief 114 into a sixth solder thief 213. That is, the circuit board 20 comprises a fifth solder thief 211, a sixth solder thief 213, a plurality of plug-in connector pads 220 and a plurality of conductive traces 230. Similar to the first and second embodiments, the plurality of conductive traces 230 each connect with one plug-in connector pad 220, and the plurality of plug-in connector pads 220 are arranged in two rows on the circuit board 20, the fifth solder thief 211 and the sixth solder thief 213 are respectively provided on both sides of the two rows of pads 220, and the two solder thieves 211, 213 are both rectangular. An area of the fifth solder thief 211 is greater than or equal to a sum of areas of three plug-in connector pads 220 adjacent to the fifth solder thief 211 and an area among the three plug-in connector pads 220; an area of the sixth solder thief 213 is greater than or equal to a sum of areas of three plug-in connector pads 220 adjacent to the sixth solder thief 213 and an area among the three plug-in connector pads 220. Therefore, the circuit board 20 with solder thieves of the third embodiment according to the present disclosure can achieve the same effect as the circuit board 10 in the second embodiment, that is, not only can prevent short circuit caused by solder bridging, but also can avoid the circuit board 20 only having a single advancing direction during wave soldering.

The circuit board with solder thieves of the embodiments according to the present disclosure described above are merely exemplary and may have various modification and variations, for example, the solder thief may be any suitable shape such as a circle, a square and the like, and the solder thieves on one side of the plug-in connector pads can be merged and the solder thieves the other side are not merged.

It is to be understood that while the preferred embodiments are illustrated and described above, the present disclosure is not limited to the specific embodiments described above, those skilled in the art may devise various modifications and variations without departing from the spirit and scope of the appended claims. Therefore, it should be noted that various modifications and variations cannot be considered to be independent of the technical spirit and expectations of the present disclosure.

What is claimed is:

1. A circuit board with solder thieves, the circuit board comprising:
a plurality of plug-in connector pads arranged in two rows on the circuit board;
a plurality of conductive traces each connecting with one plug-in connector pad; and
a first solder thief and a second solder thief, both of the first solder thief and the second solder thief being provided on one side of the two rows of plug-in connector pads, the one side being away from an advancing direction of the circuit board during wave soldering, each of an area of the first solder thief and an area of the second solder thief is greater than or equal to a sum of areas of two plug-in connector pads adjacent to corresponding one of the first solder thief and the second solder thief.

2. The circuit board according to claim 1, wherein each of the area of the first solder thief and the area of the second solder thief is greater than or equal to a sum of the areas of the two plug-in connector pads adjacent to the corresponding one of the first solder thief and the second solder thief and an area between the two plug-in connector pads.

3. The circuit board according to claim 2, wherein a sum of the area of the first solder thief and the area of the second solder thief is greater than or equal to a sum of areas of three plug-in connector pads adjacent to the first solder thief and second solder thief and an area among the three plug-in connector pads.

4. The circuit board according to claim 1, wherein the circuit board further comprises a third solder thief and a fourth solder thief, both of the third solder thief and the fourth solder thief are provided on the other side of the two rows of plug-in connector pads, the other side is opposite to the first solder thief and second solder thief, each of an area of the third solder thief and an area of the fourth solder thief is greater than or equal to a sum of areas of two plug-in connector pads adjacent to corresponding one of the third solder thief and the fourth solder thief.

5. The circuit board according to claim 4, wherein each of the area of the third solder thief and the area of the fourth solder thief is greater than or equal to a sum of the areas of the two plug-in connector pads adjacent to the corresponding one of the third solder thief and the fourth solder thief and an area between the two plug-in connector pads.

6. The circuit board according to claim 5, wherein a sum of the area of the third solder thief and the area of the fourth solder thief is greater than or equal to a sum of areas of three plug-in connector pads adjacent to the third solder thief and fourth solder thief and an area among the three plug-in connector pads.

7. The circuit board according to claim 4, wherein the first solder thief and the second solder thief are merged into a fifth solder thief, an area of the fifth solder thief is greater than or equal to a sum of areas of three plug-in connector pads adjacent to the fifth solder thief and an area among the three plug-in connector pads; the third solder thief and the fourth solder thief are merged into a sixth solder thief, an area of the sixth solder thief is greater than or equal to a sum of areas of three plug-in connector pads adjacent to the sixth solder thief and an area among the three plug-in connector pads.
